(19) United States
(12) Patent Application Publication
(10) Pub. No.: US 2009/0121616 A1
(43) Pub. Date: May 14, 2009

(54) LIGHT-EMITTING DIODE WITH LUMINESCENT CHARGE TRANSPORT LAYER

(75) Inventors: Paulus Wilhelmus Maria Blom, Groningen (NL); Jurjen Wildenman, Groningen (NL); Eric Alexander Meulenkamp, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/577,809

(22) PCT Filed: Oct. 24, 2005
(86) PCT No.: PCT/IB05/53467

§ 371 Date: Apr. 24, 2007

(30) Foreign Application Priority Data
Oct. 28, 2004 (EP) 04105356.2

(51) Int. Cl. H01L 51/54; H01L 51/50

(52) U.S. Cl. 313/504; 313/506

(57) ABSTRACT

The invention relates to a light-emitting diode comprising an anode, a cathode, a light-emitting layer, and at least one charge transport layer which has a luminescence efficiency which is at least 25% of the luminescence efficiency of the light-emitting layer. This leads to a light-emitting diode with a smaller percentage of catastrophic failures than in existing LEDs, because the charge transport layer takes over the light emission in case of a short-circuit of the light-emitting layer.

### FIELD OF THE INVENTION

The invention relates to an electroluminescent device comprising an anode, a cathode, a light-emitting layer, and at least one charge transport layer. An electroluminescent device is characterized in that it emits light when a voltage is applied and current flows. Such devices have long been known as light-emitting diodes (LEDs). The emission of light is due to the fact that positive charges (“holes”) and negative charges (“electrons”) recombine with the emission of light.

### BACKGROUND OF THE INVENTION

In the development of light-emitting diodes for electronics or photonics, use was made of inorganic semiconductors, such as gallium arsenide. In addition to semiconductor light-emitting diodes, organic LEDs (OLED's) based on vapor-deposited or solution-processed organic compounds of low molecular weight were developed. Recently, oligomers and polymers, based on e.g. substituted p-divinylbenzene, poly(p-phenylenes) and poly(p-phenylenevinylenes) (PPV), polyfluorenes and poly(spirofluorene)s have been described for the manufacture of a polymer LED (polyLED)

The most basic organic LED device comprises a single organic light-emitting layer, which is interposed between a transparent electrode as the anode and a metal electrode as the cathode. Additionally, the organic LED device may have two organic layers in order to enhance its emission efficiency, the first layer as a hole transport layer and the second layer as an organic light-emitting layer, or the first layer as an organic light-emitting layer and the second layer as an electron transport layer. These two organic layers are interposed between a transparent anode and a metal cathode. Furthermore, there are devices that have three organic layers in a given order as the hole transport layer, the organic light-emitting layer, and the electron transport layer, which layers are interposed between the two electrodes. After applying a bias to such an LED, the light emission of this device is based on the processes of moving of holes and electrons from the anode and the cathode, respectively, under the driving force of an electric field; passing their respective energy barriers; and meeting at the light-emitting layer so as to form excitons which decay from the excited state to ground state and emit light.

In a typical device, a polyLED comprises a hole transport layer, for example a PEDOT:PPS layer, and a layer of a light-emitting polymer (LEP). The charge mobility of the LEP generally is a compromise between low power, favoring high mobility, and high efficiency, favoring low mobility. For this reason an 80 nm thick LEP layer is typically used, which may result in a significant number of short-circuits, especially in large-area applications like solid-state lighting. Short-circuits cause catastrophic failures of the device in a known LED.

### SUMMARY OF THE INVENTION

An object of the invention is to provide a light-emitting diode with a smaller amount of catastrophic failures than in existing LEDs.

According to the invention a light-emitting diode comprising an anode electrode, a cathode electrode, a light-emitting layer, and at least one charge transport layer, is characterized in that the charge transport layer has a luminescence efficiency which is at least 25% of the luminescence efficiency of the light-emitting layer.

In the LED of the invention, a short-circuit does not cause catastrophic failure, as the transport layer may perform as a LED as well. In the case of a short-circuit across the thin luminescent layer, where most of the voltage drop occurs, the charge transport layer starts to emit light, thereby preventing a failure of the device and reducing the loss in light output in comparison with devices having non-emissive charge-transport layers.

In the LED of the invention, the charge transport layer has a luminescence efficiency which is at least 10%, preferably 25%, and most preferably 50% of the luminescence efficiency of the light-emitting layer. The relative efficiencies of the charge transport layer and the light-emitting layer are obtained by a comparison of the relative efficiencies of single-layer LEDs made from the two respective materials.

The thickness of the charge transport layer is related to its hole or electron mobility. The thickness of the charge transport layer is preferably between 50 and 200 nm. Above 50 nm there is low risk of a short-circuit, while below 200 nm the voltage drop across the charge transport layer is not too great. Within these limits the charge transport layer is as thick as possible, but chosen such that preferably ⅓ of the voltage drop across the device takes place across the charge transport layer. A high thickness can thus be obtained in a charge transport layer comprising a semiconductive polymer with a high mobility. The use of a thick transport layer makes for a great overall thickness of the device while maintaining a low operating voltage. This is beneficial for the process window and the power efficiency. This increase in robustness also widens the process window of PLEDs in terms of substrate roughness and substrate cleaning.

Spin casting is preferably used for the application of the different layers. A major problem for polymer-based multilayer devices is the solubility of the materials used; a multilayer cannot be realized if a spin-cast layer dissolves in the solvent of the subsequent layer. As a first approach, efficient bi-layer devices have been realized by N. C. Greenham et al., Nature 1993, 365, 628, using a precursor PPV as a hole transport layer which is insoluble after conversion. Another approach to overcome the solubility problem is to crosslink the first (hole transport) layer after deposition. However, the long UV exposure and reactive end groups needed for crosslinking strongly decrease the performance of LEDs fabricated from these materials, as described by B. Domercq et al. in J. Polym. Sc., Part B: Polym. Phys. 2003, 41, 2726. Therefore the solubility of the light-emitting layer and of the charge transport layer should be such that a spin coated first layer does not dissolve in the subsequently deposited second layer. It has been demonstrated in the past that charge transport in, for example, PPV derivatives can be enhanced by the use of long symmetrical side-chains. However, applying long symmetrical side-chains does not reduce the solubility of the polymer. The solubility can be reduced by addition of monomers with symmetrical short side chains. This can be done without loss of the enhanced charge transport properties. Consequently, a tuning of the ratio of the monomers with long and short (symmetric) side chains can serve to adjust the solubility continuously while preserving the enhanced charge transport properties. In this way, the charge transport layer, in this case a hole transport layer, can be chosen to have a lower solubility than the highly luminescent LEP layer in the same solvent. This layer of limited solubility can then be easily combined with a thin highly luminescent layer.

Preferably there is no or only a slight color difference between the light emitted by the light-emitting layer and that emitted by the charge transport layer. Color differences can be quantified by measuring the CIE values (CIE=Commission Internationale d'Eclairage) in terms of the x and y co-ordinates in the CIE chromaticity diagram. Preferably, the color differences Δx and Δy in terms of the 1931 CIE chromatic diagram between the charge transport layer and the light-emitting layer are smaller than 0.2, more preferably smaller than 0.1, and most preferably smaller than 0.05. This can be obtained either by aligning the energy levels of the HOMO and LUMU energy levels of the light-emitting layer and the charge transport layer or by adding a second light-emitting component to the layer with the greater energy difference between HOMO and LUMO energy levels. In this case the second light-emitting component is chosen such that the color of its emitted light matches the color of the light emitted by the layer having the smaller difference between the HOMO and LUMO energy levels.

Preferably the light-emitting layer and the charge transport layer have substantially aligned HOMO and LUMO energy levels. The advantage of substantially aligned HOMO and LUMO energy levels is that in the case of a short-circuit across the thin luminescent layer, and the charge transport layer taking over to act as a LED, there is no color change of the emitted light and there is no substantial energy barrier between a charge transport layer and the light-emitting layer.

The light-emitting substance may be a organic semi conductor of low molecular weight, or an oligomer or polymer semiconductor. Examples of suitable light-emitting organic semi conductors of low molecular weight are dendrimers as described in WO 99/21935, organo-metallic molecules such as tris(2-phenylpyridine)iridium (e.g. U.S. Pat. No. 6,687,266) or tris(8-hydroxyquinolinate) aluminum (e.g. U.S. Pat. No. 6,743,067).

Examples of oligomer and polymer semi conductors are (substituted)ₚ-divinylbenzene, poly(p-phenylenes), and poly(p-phenylenevinylenes) (PPVs, for example described in U.S. Pat. No. 6,423,428), polythiophenes (e.g. U.S. Pat. No. 6,723,811), polyfluorenes, and poly(spirofluorene)s (e.g. U.S. Pat. No. 6,653,438). Preferably the light-emitting layer comprises a conjugated polymer chosen from the group of (substituted)ₚ-divinylbenzenes poly(p-phenylenes), poly(p-phenylenevinylenes), polythiophenes, polyfluorenes, and poly(spirofluorene)s Different light-emitting substances may be used in different layers, using different deposition techniques. For example, a hole transport layer may be sputtered in the form of molecules of low molecular weight onto an anode, subsequently crosslinked, upon which layer a light-emitting layer of a polymer semi-conductor is spin cast. Another example is a spin cast electron transport layer on a screen-printed light-emitting layer.

### BRIEF DESCRIPTION OF THE DRAWINGS

The main aspects of the invention are schematically depicted once more in FIGS. 1 to 7?.

FIG. 1 shows the energy level schemes of various device architectures.

FIG. 2 is a schematic picture showing the presence of a particle in the LEP layer, representing a short-circuit.

FIG. 3 shows the potential distribution in the PLED device in the absence or presence of short-circuits.

FIG. 4 is a schematic representation of some possible further embodiments.

FIG. 5 plots the current density vs. voltage characteristics at room temperature of MEH-PPV, BEH-PPV, and BEH/BB-PPV 1/3 hole-only diodes.

FIG. 6 shows current density-voltage (J-V) characteristics of NRS-PPV and dual-layer LED at room temperature (a), together with light output (b).

FIG. 7 shows the quantum efficiency as function of an applied bias for NRS-PPV and dual-layer LED. The inside shows the absorption of BEH/BB-PPV 1/3 and PL of NRS-PPV.

### DETAILED DESCRIPTION OF THE DRAWINGS

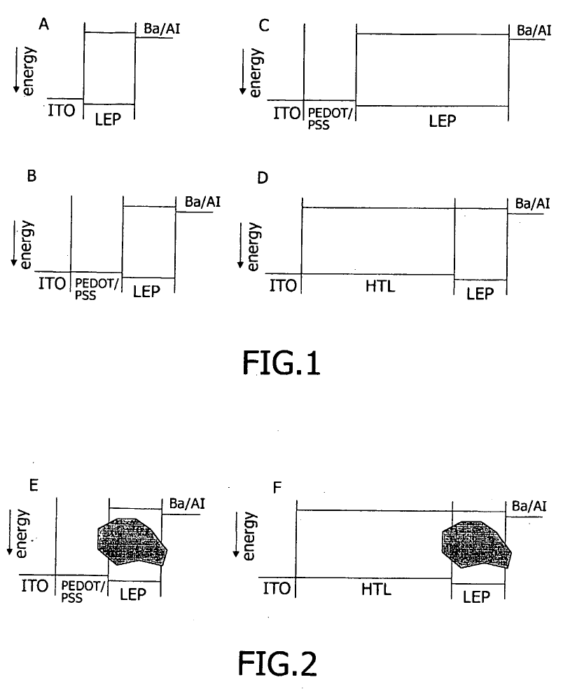

FIG. 1 shows the energy level schemes of various device architectures.

A is the most simple device known, consisting exclusively of Indium-Tin Oxide (ITO) as a transparent conductor and anode, the light-emitting polymer (LEP), and the usual PLED cathode, Ba/Al.

B is a PLED device, where a PEDOT:PSS hole transport layer is inserted. This layer is necessary, for example, as a planarization layer and prevents extreme occurrence of short-circuits. PEDOT:PSS is a doped, conducting layer with a much lower resistance than the LEP.

C describes a possible method of bringing down further the level of shorts by making the LEP layer very thick. This is not practical because the current density becomes very low, resulting in a much lower power efficiency of the device.

D describes an embodiment of the invention, where a thick hole transport layer (HTL) is used, which is undoped and accordingly insulating and luminescent, and which has a much higher mobility than the LEP layer. A further PEDOT:PSS layer may be inserted between ITO and HTL.

FIG. 2 is a schematic picture showing the presence of a particle in the LEP layer, representing a short-circuit.

E is the known PLED device, and

F is an embodiment of the invention.

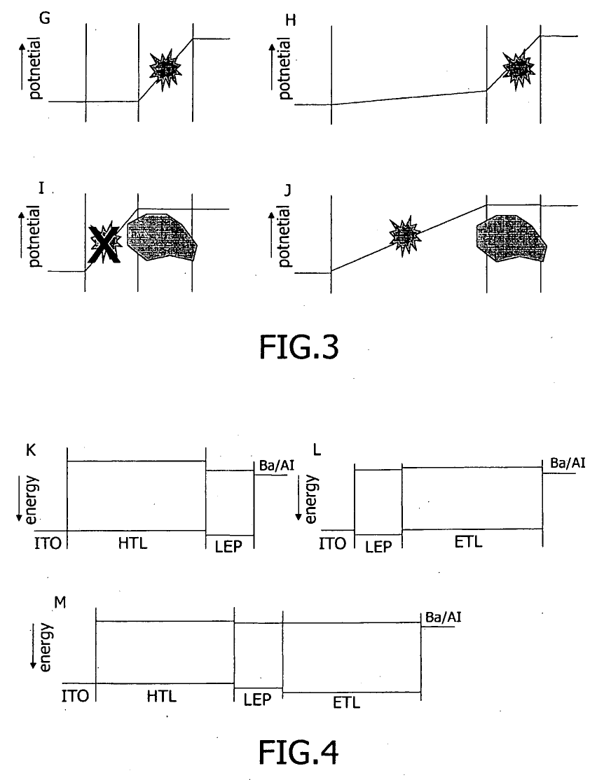

FIG. 3 shows the potential distribution in the PLED device in the absence or presence of short-circuits.

G is a known device in the absence of a short. The potential drop occurs almost entirely across the LEP layer, and light is emitted.

H is a possible embodiment of the invention in the absence of a short. The potential drop is mainly across the emissive LEP layer, which has a much lower mobility than the HTL.

I is the standard device in the presence of a short. The potential drop is entirely across the PEDOT:PSS layer, which does not emit light. The device is dead, and a very large current can flow.

J is a possible embodiment of the invention in the presence of a short. The potential drops entirely across the HTL, which emits light of the same color as the LEP. The device emits light, and no excessive current flows.

FIG. 4 is a schematic representation of some possible further embodiments.

K shows a HTL with a slightly higher conduction band level, such that electrons experience a small band offset for injection into the HTL. This improves the efficiency in the absence of a short and does not prevent? the HTL from becoming emissive in the presence of short. However, a disadvantage of a slightly higher conduction band is an increased energy gap, causing a blue shift of the emitted light in case of a short. Therefore, the hole transport layer preferably has a conduction band level which is between 0.3 and 0.4 eV higher than the conduction band level of the light-emitting layer.

L is essentially the same as D, but now with a high-mobility electron transport layer (ETL).

In M, the HTL and ETL are combined.

### DESCRIPTION OF THE PREFERRED EMBODIMENTS

Polymer synthesis: MEH-PPV, BEH-PPV, and BEH/BB-PPV 1/3 were synthesized by the MEH-PPV method in the presence of 0.5-1.0% of 4-methoxyphenol, cf. Neef et al. in Macromolecules 2000, 33, 2311. The structures of the polymers used are shown below. The precursors were carefully purified by crystallisation (3×) and the obtained polymers were purified by a second precipitation from acetone. NRS-PPV was synthesized in accordance with the procedure indicated in Adv. Mater. 1998, 10, 1340:

Polymer analysis: Molecular weights were determined by gel permeation chromatography (GPC); they were measured in trichlorobenzene at 135° C. and calibrated with polystyrene standards.

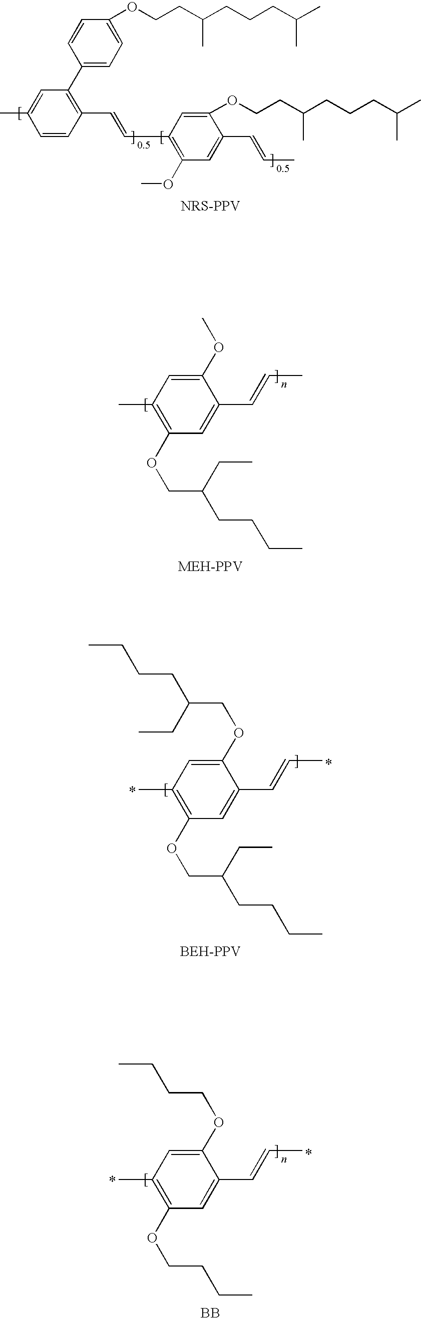

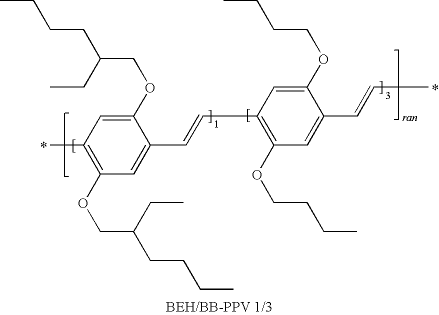

The combination of BEH-PPV and BB-PPV in various ratios in copolymers can induce a variation from insoluble in toluene (pure BB-PPV) to highly soluble in toluene (pure BEH-PPV), depending on the amount of BB-PPV in the copolymer. The solubility in toluene of BEH/BB-PPV in various ratios 1:x (x=1-3) drops from 0.2% for BEH/BB-PPV 1/1 to less than 0.1% for BEH/BB-PPV 1/3.

Poly[{2-(4-(3′,7′-dimethyloctyloxyphenyl))}-co-{2-methoxy-5-(3′,7′-dimethyloctyloxy)}-1,4-phenylenevinylene] (NRS-PPV) used in the devices is soluble in a wide range of solvents with a hole mobility of only 1.5×10⁻¹² m² V s at low electric fields at room temperature when spin-coated from toluene.

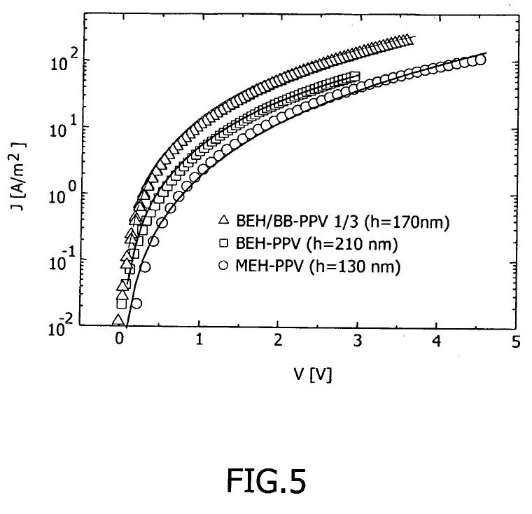

The analysis of the J-V measurements as shown in FIG. 5 with a space-charge limited model (SCL) and as described by P. W. M. Blom et al. in Mat. Sc. and Engineering 2000, 27, 53, provides direct information about the hole mobility. The solid lines represent the best fit with the SCL model, based on the hole mobility as a single parameter. At low electric fields and room temperature, the hole mobility in MEH-PPV amounts to 5×10⁻¹¹ m²/V s.

Table 1 below lists the mobility, molecular weight, and solubility of the polymers

TABLE 1

| | | | | Solubility (%) | |
|---|---|---|---|---|---|
| | | | | | chloro- |
| Polymer | μ(E = 0)_{RT} | Mw [g/mol] | Mn [g/mol] | toluene | form |
| NRS- | 1.5 × 10⁻¹² | 1.0 × 10⁶ | 1.9 × 10⁵ | 1 | 1 |
| PPV | | | | | |
| MEH- | 5.0 × 10⁻¹¹ | 2.1 × 10⁵ | 6.3 × 10⁴ | 1 | 1 |
| PPV | | | | | |
| BEH- | 2.0 × 10⁻⁹ | 5.5 × 10⁵ | 1.3 × 10⁵ | 1 | 1 |
| PPV | | | | | |
| BB | — | — | — | 0 | 0.2 |
| BEH/BB- | 1.2 × 10⁻⁹ | 5.7 × 10⁵ | 4.2 × 10⁵ | <0.1 | 0.6 |
| PPV 1/3 | | | | | |

Device preparation: Pre-patterned glass/ITO-substrates were cleaned ultrasonically in acetone and isopropyl alcohol and were given an UV-ozone treatment. The polymer layer was spin-coated from a toluene or chloroform solution in a N₂ atmosphere. Finally, an ˜5 nm Ba layer and an ˜100 nm Al protecting layer for LEDs and an ˜80 nm Au layer for hole-only diodes were deposited by thermal evaporation under vacuum (1×10⁻⁶ mbar).

Device characterization: The polymer thickness was measured with a Dektak profile analyzer. The active areas of the devices varied between 7.6 and 99 mm². The electrical measurements were done with a Keithley 2400 Sourcemeter in a N₂ atmosphere. The light output was recorded by a calibrated photodiode connected to a Keithley 6514 electrometer. The current density-voltage (J-V) characteristics of these devices were obtained in a nitrogen atmosphere within a temperature range of 190-300 K. All the measurements were performed within a few hours after the preparation of the samples in order to avoid oxidation of the polymer or the metal.

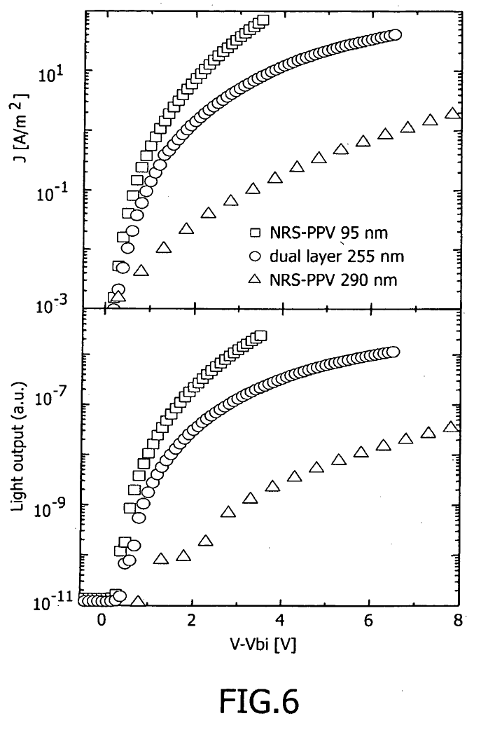

A dual polymer layer LED was constructed with BEH/BB-PPV 1/3 as a hole transport layer and NRS-PPV as an emission layer. The photoluminescence efficiency of NRS-PPV was 20% and of BEH/BB-PPV 9%, both measured with an integrating sphere. FIG. 6 shows the J-V characteristics of devices based on a single-layer NRS-PPV LED with thickness 95 nm, a double layer of BEH/BB-PPV 1/3, and NRS-PPV (FIG. 6a) together with the respective light output values (FIG. 6b). The thicknesses of the layers in the dual-layer diode are 160 nm for BEH/BB-PPV 1/3 and 95 nm for NRS. The data of a single-layer NRS-based LED with comparable thickness as the dual-layer device is also shown by way of reference. When a bias is applied to the diode, the holes are efficiently transported through the BEH/BB-PPV 1/3 and subsequently recombine with electrons in the NRS-PPV layer. The holes can directly enter the NRS-PPV and are not hindered by an energy barrier at the interface, since the HOMO and LUMO levels of the two polymers align. It can be observed from FIGS. 6a, b that at the same operating voltage both the current density and the light output of the double layer are smaller than those of the single-layer NRS-PPV diode of 95 nm. Since the current in the BEH/BB-PPV is space charge limited, a very low voltage drop across this layer implies that electrostatically only a small amount of charge carriers is allowed in this layer. Therefore, a certain voltage drop across this layer is required to fill up the layer with charge carriers in order to make the hole transport layer highly conductive.

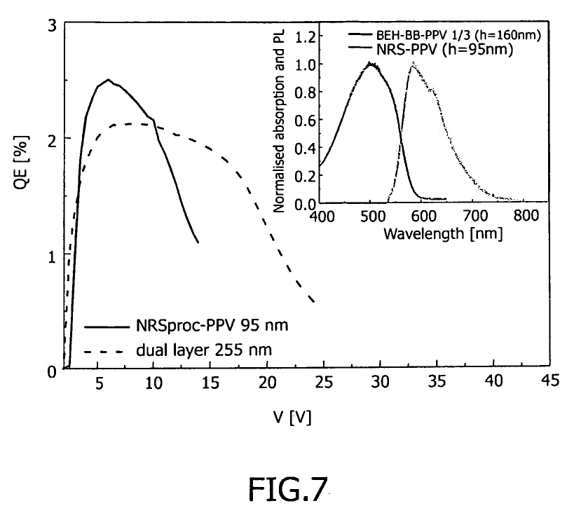

FIG. 7 shows the quantum efficiency (QE) (photon/charge carrier) as a function of an applied bias for NRS-PPV and dual-layer LEDs. The inside shows the absorption of BEH/BB-PPV 1/3 and PL of NRS-PPV.

As is apparent from FIG. 7, the maximum efficiency of the double-layer diode is almost 20% less than that of the single-layer NRS-PPV diode. There are two reasons for this: First, the absorbance and emission spectrum of BEH/BB-PPV 1/3 is red-shifted with respect to the NRS-PPV. Therefore, as shown in the inset of FIG. 7, the absorption spectrum of BEH/BB-PPV slightly overlaps the emission spectrum of NRS-PPV, and part of the generated light is absorbed in the hole transport layer. Second, since the HOMO and LUMO levels of the hole transport and luminescent layers are aligned, the electrons are not blocked at their interface. Therefore, a small part of the electroluminescence is generated in the low-luminescence BEH/BB-PPV layer, thereby reducing the maximum quantum efficiency of the device. The advantage of using aligned energy levels is that it strongly simplifies the analysis of the performance of this dual-layer test device. The efficiency of the single layer NRS-PPV PLED drops very fast for V>7 V, due to the strong quenching of the luminescence efficiency at high fields. Finally, the single-layer device typically breaks down at 12-13 V. The efficiency of the dual-layer device only gradually decreases from 7 V to 18 V; the device according to the invention finally breaks down at 25 to 26 V. At 10 V the efficiency of the two devices is the same, at a typical light output of ˜10000 cd/m². The increased efficiency at high voltages as well as the increased robustness clearly demonstrates the potential of multilayer devices.

1. Light-emitting diode comprising an anode electrode, a cathode electrode, a light-emitting layer, and at least one charge transport layer, characterized in that the charge transport layer has a luminescence efficiency which is at least 25% of the luminescence efficiency of the light-emitting layer.

2. Light-emitting diode, wherein the color differences Δx and Δy in terms of the 1931 CIE chromaticity diagram between the charge transport layer and the light-emitting layer are smaller than 0.2.

3. Light-emitting diode according to claim 1, wherein the light-emitting layer and the charge transport layer have substantially aligned HOMO and LUMO energy levels.

4. Light-emitting diode according to claim 1, wherein at least two charge transport layers have a luminescence efficiency that is at least 25% of the luminescence efficiency of the light-emitting layer.

5. Light-emitting diode according to 1, wherein the charge transport layer is a hole transport layer.

6. Light-emitting diode according to claim 5, wherein the hole transport layer has a conduction band level that is between 0.3 and 0.4 eV higher than the conduction band level of the light-emitting layer.

7. Light-emitting diode according to claim 1, wherein the light-emitting layer comprises a conjugated polymer chosen from the group of (substituted)p-divinylbenzenes poly(p-phenylenes), poly(p-phenylenevinylenes), polythiophenes, polyfluorenes, and poly(spirofluorene)s.
